(19) United States
(12) Patent Application Publication
(10) Pub. No.: US 2011/0198705 A1
(43) Pub. Date: Aug. 18, 2011

(54) Integrated resistor using gate metal for a resistive element

(75) Inventors: Xiangdong Chen, Irvine, CA (US); Wei Xia, Irvine, CA (US)

(73) Assignee: BROADCOM CORPORATION, Irvine, CA (US)

(21) Appl. No.: 12/658,996

(22) Filed: Feb. 18, 2010

(51) Int. Cl. H01L 27/06; H01L 21/28

(52) U.S. Cl. 257/380; 438/382; 438/238; 257/E21.616; 257/E21.195

(57) ABSTRACT

According to one disclosed embodiment, a method for fabricating an integrated resistor in a semiconductor die includes forming a high-k dielectric over a substrate and a metal layer over the high-k dielectric, where the metal layer forms a resistive element of the integrated resistor. The method further includes forming an un-doped polysilicon layer over the metal layer, where a portion of the un-doped polysilicon layer can be selectively doped and used to form a conductive path to the resistive element of the integrated resistor. In one embodiment, the metal layer comprises a gate metal. In one embodiment, the integrated resistor is formed substantially concurrently with one or more transistors without requiring additional fabrication process steps. One disclosed embodiment is an integrated resistor formed according to the disclosed method.

### BACKGROUND OF THE INVENTION

1. Field of the Invention

The present invention is generally in the field of semiconductors. More particularly, the present invention is in the field of resistor fabrication in semiconductor dies.

2. Background Art

Integrated resistors comprise a fundamental building block of integrated analog and mixed signal circuits fabricated on semiconductor dies. A conventional integrated resistor typically uses unsilicided, doped polysilicon as its resistive element (poly resistor), which results in a characteristic resistance for a conventional poly resistor of 500 to 1000 ohms/sq. Total effective resistances can be designed for, for example, by forming multiple poly resistors connected in series or parallel, which takes up additional space on a semiconductor die, or by adjusting the geometry of the polysilicon resistive element, which is limited by the achievable pattern resolution.

A conventional poly resistor can be fabricated, for example, by forming a doped polysilicon layer and then selectively etching the polysilicon to a geometry corresponding to a desired resistance. The resulting resistive element can then be electrically connected to other semiconductor devices by forming conductive contacts at the ends of the resistive element using conventional techniques. However, because the geometry is limited by the achievable pattern resolution, and because the characteristic resistance for conventional poly resistors is relatively large, conventional techniques using conventional poly resistors either require more processing steps or undesirably large areas to reach smaller effective resistances.

Thus, there is a need to overcome the drawbacks and deficiencies in the art by providing an integrated resistor that increases design flexibility while minimizing area consumption and the number of additional required processing steps.

### SUMMARY OF THE INVENTION

An integrated resistor using gate metal for a resistive element, substantially as shown in and/or described in connection with at least one of the figures, as set forth more completely in the claims.

### BRIEF DESCRIPTION OF THE DRAWINGS

FIG. 1 illustrates a top-down and cross-sectional view of a conventional poly resistor.

FIG. 2 shows a flowchart illustrating steps taken to implement an embodiment of the present invention.

FIG. 3A illustrates a cross-sectional view, which includes a portion of a wafer processed according to an embodiment of the invention, corresponding to an initial step in the flowchart in FIG. 2.

FIG. 3B illustrates a cross-sectional view, which includes a portion of a wafer processed according to an embodiment of the invention, corresponding to an intermediate step in the flowchart in FIG. 2.

FIG. 3C illustrates a cross-sectional view, which includes a portion of a wafer processed according to an embodiment of the invention, corresponding to an intermediate step in the flowchart in FIG. 2.

FIG. 3D illustrates a cross-sectional view, which includes a portion of a wafer processed according to an embodiment of the invention, corresponding to an intermediate step in the flowchart in FIG. 2.

FIG. 3E illustrates a cross-sectional view, which includes a portion of a wafer processed according to an embodiment of the invention, corresponding to a final step in the flowchart in FIG. 2.

### DETAILED DESCRIPTION OF THE INVENTION

The present invention is directed to an integrated resistor using gate metal for a resistive element. The following description contains specific information pertaining to the implementation of the present invention. One skilled in the art will recognize that the present invention may be implemented in a manner different from that specifically discussed in the present application. Moreover, some of the specific details of the invention are not discussed in order not to obscure the invention.

The drawings in the present application and their accompanying detailed description are directed to merely exemplary embodiments of the invention. To maintain brevity, other embodiments of the present invention are not specifically described in the present application and are not specifically illustrated by the present drawings. It should be understood that unless noted otherwise, like or corresponding elements among the figures may be indicated by like or corresponding reference numerals. Moreover, the drawings and illustrations in the present application are generally not to scale, and are not intended to correspond to actual relative dimensions.

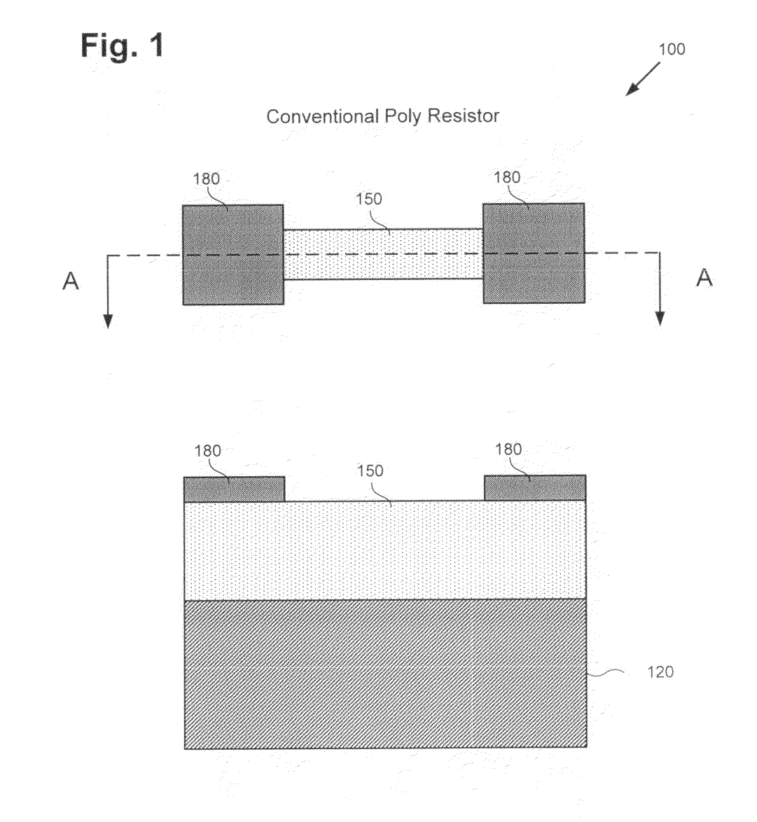

FIG. 1 shows the structure of a polysilicon resistor (poly resistor) in general use in the conventional art. As shown in FIG. 1, conventional poly resistor 100 comprises isolation region 120, doped polysilicon resistive element 150, and patterned silicide patches 180. Isolation region 120 can be a shallow trench isolation (STI) region, for example, and acts to electrically isolate conventional poly resistor 100 from an underlying semiconductor wafer or die (not shown in FIG. 1).

Doped polysilicon resistive element 150 typically has a characteristic resistance of 500 to 1000 ohms/sq, for example, and can be patterned to form a geometry corresponding to a desired total effective resistance for conventional poly resistor 100. Patterned silicide patches 180 form a conductive path to doped polysilicon resistive element 150, and facilitate integration of conventional poly resistor 100 with other semiconductor structures.

Conventional poly resistor 100 exemplifies the problems that the present invention resolves. Conventional poly resistor 100 can require at least one additional process step beyond those required to fabricate a conventional P or N channel field effect transistor (PFET or NFET) gate stack, or other such CMOS structures, as described below. Conventional poly resistor 100 also has a relatively large characteristic resistance, which, along with limits on lithographic resolution, reduces flexibility in semiconductor device design by forcing a particular design to use multiple conventional poly resistors connected in parallel to produce a low total effective resistance, which takes up valuable semiconductor die real estate in addition to the aforementioned process inefficiencies.

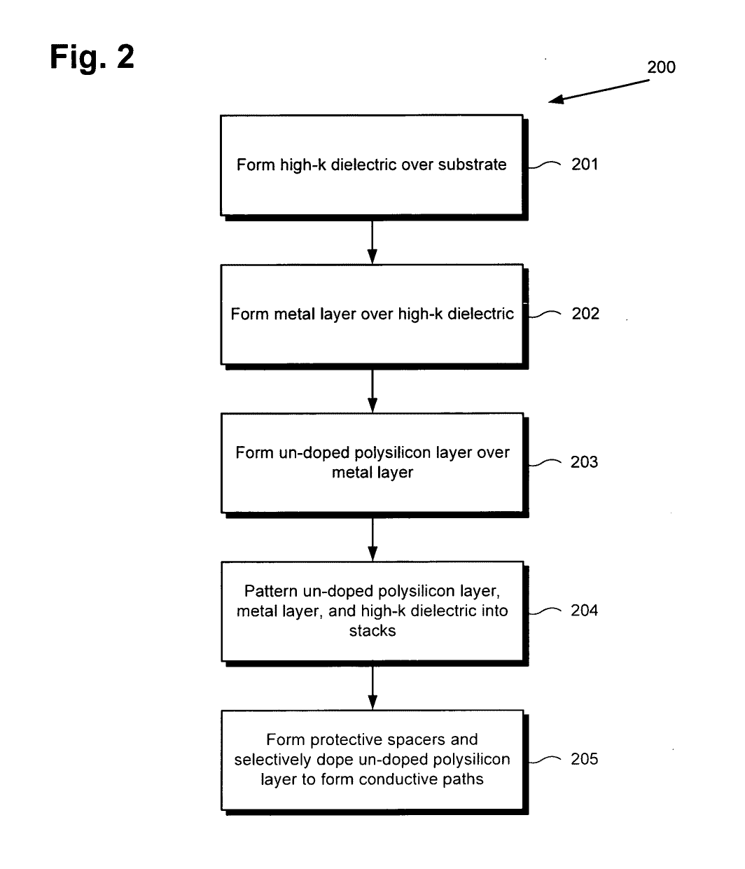

FIG. 2 shows a flow chart illustrating a method according to an embodiment of the present invention that resolves inefficiencies inherent in using a conventional poly resistor. Certain details and features have been left out of flowchart 200 that are apparent to a person of ordinary skill in the art. For example, a step may consist of one or more substeps or may involve specialized equipment or materials, as known in the art. Steps 201 through 205 indicated in flowchart 200 are sufficient to describe one embodiment of the present invention; however, other embodiments of the invention may make use of steps different from those shown in flowchart 200. It is noted that the processing steps shown in flowchart 200 are performed on a portion of processed wafer, which, prior to step 201, includes, among other things, a substrate, such as a silicon substrate, and isolation regions, such as STI regions, formed in the substrate using conventional techniques. The wafer is also referred to simply as a wafer or a semiconductor die or simply a die in the present application.

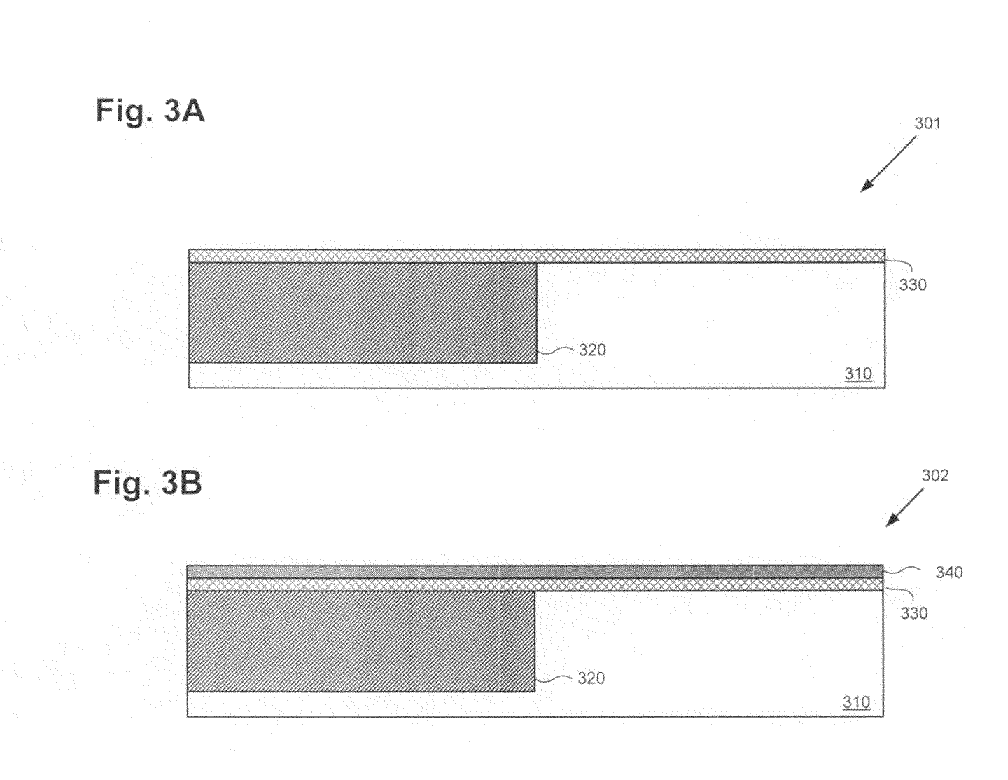

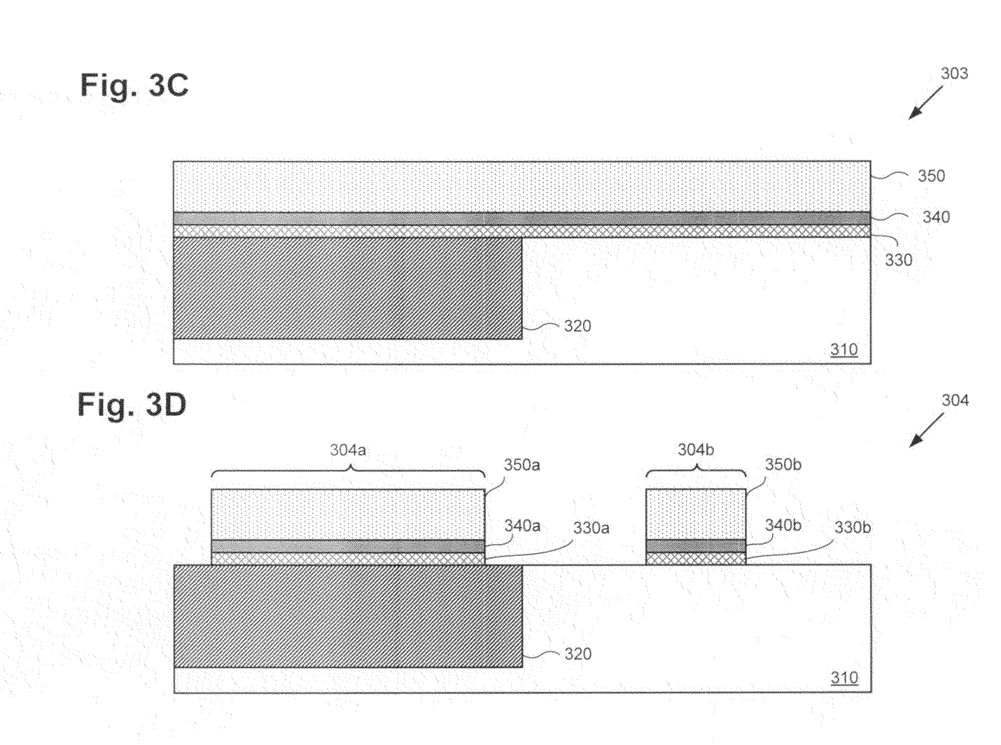

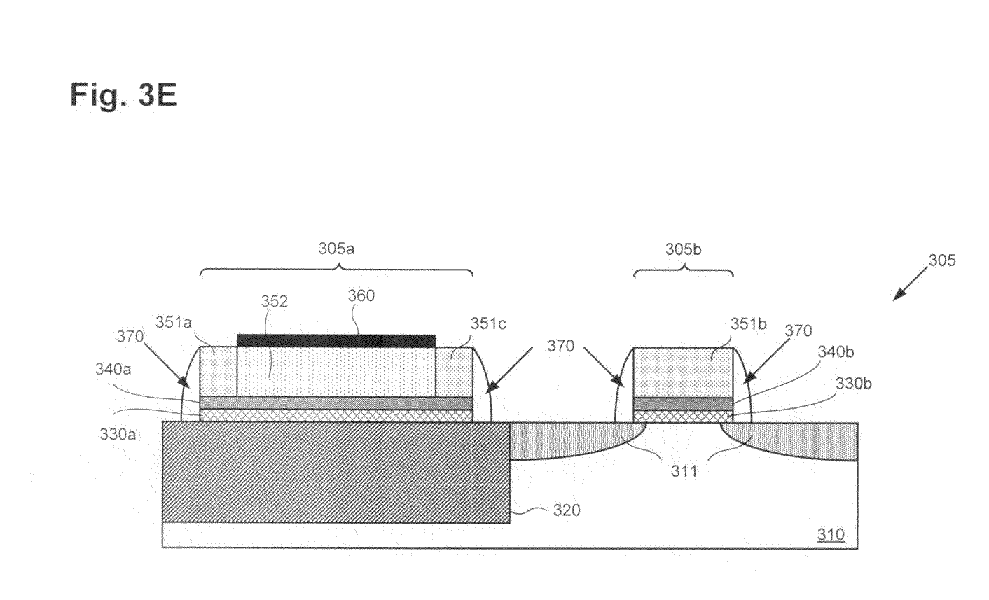

Moreover, FIGS. 3A through 3E illustrate the result of performing steps 201 through 205 of flowchart 200, respectively. For example, FIG. 3A shows a semiconductor structure after processing step 201, FIG. 3B shows the structure in FIG. 3A after processing step 202, FIG. 3C shows the structure in FIG. 3B after processing step 203, and so forth.

Referring now to step 201 of the method embodied in FIG. 2, step 201 of flowchart 200 comprises forming a high dielectric constant (high-k) dielectric over a substrate of a semiconductor die. FIG. 3A shows a structure including substrate 310 and isolation region 320, after completion of step 201 of flowchart 200 in FIG. 2, where high-k dielectric 330 can be formed over both isolation region 320 and substrate 310. For example, substrate 310 can be a silicon substrate, and isolation region 320 can be an STI region comprised of silicon oxide or other dielectric material. High-k dielectric 330 can be, for example, an approximately 1.5 to 3 nm thick layer of a high-k gate dielectric (e.g. a high-k dielectric suitable for forming a PFET gate dielectric) comprising, for example, a metal oxide such as hafnium oxide (HfO₂), zirconium oxide (ZrO₂), or the like, and can be formed by, for example, employing a physical vapor deposition (PVD) process, a chemical vapor deposition (CVD) process, or other deposition process as known in the art.

Isolation region 320 can be configured to electrically isolate at least one integrated resistor formed on its surface from substrate 310. Substrate 310 can be configured to support, simultaneously, formation of both isolation region 320 and a PFET gate stack (described further below), or multiple embodiments of each. High-k dielectric 330 can be configured to serve, simultaneously, both as a base material for the present invention and as a gate dielectric for a PFET gate stack, or it can be configured to serve similarly for multiple embodiments of each.

Continuing with step 202 in FIG. 2 and referring to FIG. 3B, step 202 of flowchart 200 comprises forming metal layer 340 over high-k dielectric 330. Metal layer 340 can be, for example, an approximately 5 to 10 nm thick layer of gate metal comprising, for example, molybdenum (Mo), ruthenium (Ru), tantalum carbide nitride (TaCN), or other gate metal suitable for utilization in a PFET gate, and can be formed over high-k dielectric 330 by, for example, employing a physical vapor deposition (PVD) process, a chemical vapor deposition (CVD) process, or other deposition process as known in the art. Metal layer 340 can be configured to form a resistive element of at least one resistor stack (described further below) having, for example, a characteristic resistance of between approximately 50 to 200 ohms/sq. Concurrently, metal layer 340 can be configured to form a gate metal layer for at least one PFET gate stack.

FIG. 3C shows the structure in FIG. 3B after completion of step 203 of flowchart 200 in FIG. 2, which comprises forming un-doped polysilicon layer 350 over metal layer 340. Un-doped polysilicon layer 350 can be, for example, an approximately 30 to 100 nm thick layer of un-doped polysilicon, or some other high resistance material suitable for later doping to form a patterned conductive path to metal layer 340 (e.g. suitable for forming a PFET gate), and can be formed over metal layer 340 by, for example, employing a low pressure chemical vapor deposition (LPCVD) process or other suitable deposition process as known in the art. Un-doped polysilicon layer 350 can be configured to serve both as an insulator and, when appropriately doped as described below, as a patterned conductive path to metal layer 340.

Moving now to step 204 of FIG. 2 and referring to FIG. 3D, step 204 of flowchart 200 comprises patterning un-doped polysilicon layer 350, metal layer 340, and high-k dielectric 330 to form stacks. FIG. 3D shows the structure in FIG. 3C after completion of step 204 of flowchart 200 in FIG. 2, where high-k dielectric 330, metal layer 340 and un-doped polysilicon layer 350 of FIG. 3C have been patterned into, for example, resistor stack 304a and PFET gate stack 304b. During the patterning process, which can include masking and etch steps, selected portions of high-k dielectric 330, metal layer 340 and un-doped polysilicon layer 350 can be concurrently removed from both substrate 310 and isolation region 320 in one or more etch steps, meaning the respective stacks can be formed without requiring additional processing steps with respect to a typical PFET fabrication process. Resistor stack 304a can be formed so that metal layer 340a in resistor stack 304a can exhibit a geometry corresponding to a desired total effective resistance for a completed integrated resistor.

Also shown in FIG. 3D are high-k dielectric 330a and un-doped polysilicon layer 350a of resistor stack 304a and high-k dielectric 330b, metal layer 340b and un-doped polysilicon layer 350b of PFET gate stack 304b, where high-k dielectrics 330a and 330b can be patterned segments of previously described high-k dielectric 330, metal layers 340a and 340b can be patterened segments of previously described metal layer 340, and un-doped polysilicon layers 350a and 350b can be patterned segments of previously described un-doped polysilicon layer 350.

Continuing with step 205 of FIG. 2 and referring to FIG. 3E, step 205 of flowchart 200 comprises forming spacers 370 and selectively doping portions of un-doped polysilicon layers 350a and 350b to form doped segments 351a, 351b, and 351c. FIG. 3E shows the structure in FIG. 3D after completion of step 205 of flowchart 200 in FIG. 2, where un-doped polysilicon layers 350a and 350b of FIG. 3D can be selectively doped in a pattern that can form doped segments 351a, 351b and 351c, yet leave un-doped segment 352 un-doped.

As shown in FIG. 3E, protective spacers 370 can be formed adjacent to the sides of resistor stack 305a and PFET gate stack 305b. Spacers 370 can comprise silicon oxide or other dielectric material as known in the art, and can be formed, for example, by conformally depositing a layer of dielectric material, such as silicon oxide, over resistor stack 305a and PFET gate stack 305b by employing a CVD process or other deposition process and then appropriately etching the layer of dielectric material in an etch-back process.

Doped segments 351a, 351b and 351c can be formed by, for example, first forming blocking pattern 360 using, for example, a mask and etch process as known in the art, where a shape of blocking pattern 360 can, in part, define a geometry of metal layer 340a corresponding to a desired total effective resistance for a completed integrated resistor. As known in the art, blocking pattern 360 can comprise, for example, photoresist, or some other material suitable to a patterning process, and can be configured to block implantation of dopant in material situated beneath blocking pattern 360.

Next, the non-blocked portions of un-doped polysilicon layers 350a and 350b of FIG. 3D and the exposed surface of substrate 310 can be selectively doped, for example, with a P type dopant using, for example, implant and annealing process steps as known in the art, which can result in (P type) conductive doped segments 351a, 351b and 351c in the non-blocked portions of un-doped polysilicon layers 350a and 350b of FIG. 3D, and in (P type) source/drain regions 311 in substrate 310. While not emphasized in this embodiment, blocking pattern 360 can be extended to block doping of other areas of the semiconductor die, and such a blocking pattern is typically used to do so in a conventional fabrication process, meaning that formation of blocking pattern 360 and subsequent selective doping can take place, as in the present invention, without adding additional required steps to a typical fabrication process.

Also shown in FIG. 3E, resistor stack 305a includes high-k dielectric 330a situated over isolation region 320, metal layer 340a situated over high-k dielectric 330a, doped segments 351a and 351c situated over metal layer 340a, and un-doped segment 352 also situated over metal layer 340a, but disposed between doped segments 351a and 351c. In resistor stack 305a, high-k dielectric 330a is configured to form a base material, metal layer 340a is configured to form a resistive element, doped segments 351a and 351c are configured to form a conductive path to the resistive element, and un-doped segment 352 is configured to insulate the resistive element.

Correspondingly, PFET gate stack 305b in FIG. 3E includes high-k dielectric 330b situated over substrate 310 and source/drain regions 311, metal layer 340b situated over high-k dielectric 330b, and doped segment 351b situated over metal layer 340b. In PFET gate stack 305b, high-k dielectric 330b is configured to form a PFET gate dielectric, metal layer 340b is configured to form a PFET metal gate, and doped segment 351b is configured to form a conductive path to a PFET metal gate, which, in conjunction with a PFET metal gate, forms a PFET gate.

After completing step 205 of FIG. 2, resulting in the structure shown in FIG. 3E, known processing steps can be performed to, for example, form patterned silicide patches over doped segments 351a, 351b and 351c (but not over un-doped segment 352) and over source/drain regions 311 to facilitate formation of metal contacts and general integration into analog and mixed signal semiconductor circuits, such as integrated circuits (ICs) containing multiple NFETs, PFETs, integrated inductors, integrated capacitors, and integrated resistors formed according to the present inventive concepts). These processing steps of forming patterned silicide patches are well known in the art, and are configured so they can be completed without adding additional required steps to a typical fabrication process.

In an embodiment of the invention shown in FIGS. 3A through 3E, resistor stack 305a corresponds to PFET gate stack 305b such that metal layer 340a of resistor stack 305a (i.e. the resistive element of resistor stack 305a) can comprise the same gate metal as the metal gate in PFET gate stack 305b. However, in another embodiment, the process for forming resistor stack 305a can be suitably modified to correspond to a NFET gate stack process (not shown). Thus, in such embodiment, the resistive element of resistor stack 305a can comprise the same gate metal as a metal gate in an NFET gate stack (not shown).

Therefore, by using a high-k gate dielectric material for a base material and a gate metal for a resistive element, the process for forming an embodiment of the disclosed integrated resistor (resistor stack 305a) is compatible with multiple high-k metal gate processes for advanced process technologies, such as 45 nm and smaller process technologies. Consequently, by forming at least one integrated resistor in at least one region of a substrate while concurrently forming at least one PFET or NFET gate stack in another region of a substrate, an embodiment of the present invention can advantageously form an integrated resistor without requiring additional masks or process steps beyond those required to form the PFET or NFET gate stacks.

In addition, by using gate metal for a resistive element, an embodiment of the invention's integrated resistor can provide a characteristic resistance between approximately 50 to 200 ohms/sq, which allows formation of integrated resistors with relatively low total effective resistances without requiring multiple integrated resistors connected in parallel, thereby advantageously reducing the die area required to implement a relatively low total effective resistance.

Thus, as discussed above, the present invention provides an integrated resistor that uses a gate dielectric material, such as a high-k gate dielectric material, as a base material, a gate metal for a resistive element, and a dopable high resistance material, such as un-doped polysilicon, both to insulate and provide a conductive path to its resistive element. As such, the invention's integrated resistor can be advantageously formed concurrently with NFET or PFET gate stacks without requiring additional masks or process steps beyond those required to form NFET or PFET gate stacks. By requiring no additional processing steps, the present invention provides an integrated resistor that can be fabricated at a significantly lower cost compared to a conventional poly resistor, as is described above. Additionally, because the present invention provides an integrated resistor having a characteristic resistance that is lower than that attainable by a conventional poly resistor, the present invention increases flexibility in the design of semiconductor circuits, which can lead, for example, to advantageous reductions in device size and complexity.

From the above description of the invention it is manifest that various techniques can be used for implementing the concepts of the present invention without departing from its scope. Moreover, while the invention has been described with specific reference to certain embodiments, a person of ordinary skill in the art would appreciate that changes can be made in form and detail without departing from the spirit and the scope of the invention. Thus, the described embodiments are to be considered in all respects as illustrative and not restrictive. It should also be understood that the invention is not limited to the particular embodiments described herein but is capable of many rearrangements, modifications, and substitutions without departing from the scope of the invention.

1. An integrated resistor fabricated in a semiconductor die, said integrated resistor comprising:
a high-k dielectric formed over a substrate of said semiconductor die;
a gate metal layer formed over said high-k dielectric;
a high resistance material formed over said gate metal layer;
said gate metal layer configured to provide a resistive element of said integrated resistor.

2. The integrated resistor of claim 1, wherein said high-k dielectric is formed over an isolation region in said substrate.

3. The integrated resistor of claim 1, wherein said high resistance material comprises un-doped polysilicon.

4. The integrated resistor of claim 1, wherein said high resistance material comprises at least one doped segment, said at least one doped segment of said high resistance material configured to form a conductive path to said resistive element of said integrated resistor.

5. The integrated resistor of claim 4, further comprising at least one patterned silicide patch formed over said at least one doped segment of said high resistance material.

6. A method for fabricating an integrated resistor in a semiconductor die, said method comprising:
forming a high-k dielectric over a substrate of said semiconductor die;
forming a gate metal layer over said high-k dielectric;
forming a high resistance material over said gate metal layer;
said gate metal layer configured to provide a resistive element of said integrated resistor.

7. The method of claim 6, wherein said high-k dielectric is formed over an isolation region in said substrate.

8. The method of claim 6, wherein said high resistance material comprises un-doped polysilicon.

9. The method of claim 6, further comprising forming at least one doped segment of said high resistance material, said at least one doped segment of said high resistance material configured to form a conductive path to said resistive element of said integrated resistor.

10. The method of claim 9, further comprising forming at least one patterned silicide patch over said at least one doped segment of said high resistance material.

11. The method of claim 9, further comprising forming a transistor gate stack concurrently with said integrated resistor.

12. The method of claim 11, wherein said high-k dielectric is configured to comprise a gate dielectric of said transistor gate stack, and said gate metal layer and said at least one doped segment of said high resistance material are configured to comprise a gate of said transistor gate stack.

13. The method of claim 6 further comprising forming spacers adjacent to respective sides of said integrated resistor.

14. An integrated circuit (IC) including at least one CMOS device and at least one integrated resistor, said at least one integrated resistor comprising:
a high-k dielectric formed over a substrate of said semiconductor die;
a gate metal layer formed over said high-k dielectric;
a high resistance material formed over said gate metal layer;
said gate metal layer configured to provide a resistive element of said integrated resistor.

15. The IC of claim 14, wherein said high-k dielectric is formed over an isolation region in said substrate.

16. The IC of claim 14, wherein said high resistance material comprises un-doped polysilicon.

17. The IC of claim 14, further comprising at least one doped segment of said high resistance material, said at least one doped segment of said high resistance material configured to form a conductive path to said resistive element of said integrated resistor.

18. The IC of claim 17, further comprising at least one patterned silicide patch over said at least one doped segment of said high resistance material.

19. The IC of claim 17, further comprising a transistor gate stack, said high-k dielectric configured to comprise a gate dielectric of said transistor gate stack, and said gate metal layer and said at least one doped segment of said high resistance material configured to comprise a gate of said transistor gate stack.

20. The IC of claim 14, further comprising spacers formed adjacent to respective sides of said integrated resistor.
